(19) United States
(12) Patent Application Publication
(10) Pub. No.: US 2024/0378331 A1
(43) Pub. Date: Nov. 14, 2024

(54) DIGITAL TWIN-BASED FLOOR LAYOUT GENERATION

(71) Applicant: Accenture Global Solutions Limited, Dublin 4 (IE)

(72) Inventors: Abhinav UPADHYAY, Hazaribag (IN); Alpana DUBEY, Bangalore (IN); Shubhashis SENGUPTA, Bangalore (IN)

(73) Assignee: Accenture Global Solutions Limited, Dublin 4 (IE)

(21) Appl. No.: 18/316,940

(22) Filed: May 12, 2023

(51) Int. Cl. G06F 30/13

(52) U.S. Cl. CPC G06F 30/13

(57) ABSTRACT

In some examples, digital twin-based floor layout generation may include receiving, for a floor plan that is to be generated, an activity map that includes movement of at least one user within a digital twin of a specified area. Based on the activity map, embedding vectors may be generated for each room type of a plurality of room types in the specified area. An input boundary feature map may be received. The floor plan may be generated based on an analysis of the embedding vectors for each room type of the plurality of room types and based on an analysis of the input boundary feature map.

### BACKGROUND

With respect to floor plan design of residential as well as non-residential facilities, tools, such as computer-aided design (CAD) tools, may be used to design a floor plan. Depending on the complexity of the floor plan design, various levels of expertise may be required for utilization of such tools. In an example of a floor plan design, an architect may obtain the requirements from a client in the form of room types, number of rooms, room sizes, plot boundary, the connection between rooms, etc., sketch out rough floor plans and collect feedback from the client, refine the sketched plans, and design and generate the floor plan using CAD tools. The experience of the architect may become a significant factor in the quality of the floor plan design.

### BRIEF DESCRIPTION OF DRAWINGS

Features of the present disclosure are illustrated by way of example and not limited in the following figure(s), in which like numerals indicate like elements, in which:

FIG. 1 illustrates a layout of a digital twin-based floor layout generation apparatus in accordance with an example of the present disclosure;

FIG. 2 illustrates a layout of a digital twin of a home to illustrate operation of the digital twin-based floor layout generation apparatus of FIG. 1, in accordance with an example of the present disclosure;

FIG. 3 illustrates a layout of a digital twin of a factory to illustrate operation of the digital twin-based floor layout generation apparatus of FIG. 1, in accordance with an example of the present disclosure;

FIG. 4 illustrates an architecture of the digital twin-based floor layout generation apparatus of FIG. 1, in accordance with an example of the present disclosure;

FIG. 5 illustrates an architecture of an image synthesizer of the digital twin-based floor layout generation apparatus of FIG. 1, in accordance with an example of the present disclosure;

FIG. 6 illustrates an architecture of a discriminator of the digital twin-based floor layout generation apparatus of FIG. 1, in accordance with an example of the present disclosure;

FIGS. 7A and 7B illustrate results to illustrate operation of the digital twin-based floor layout generation apparatus of FIG. 1, in accordance with an example of the present disclosure;

FIG. 8 illustrates results to illustrate operation of the digital twin-based floor layout generation apparatus of FIG. 1, in accordance with an example of the present disclosure;

FIG. 9 illustrates an example block diagram for digital twin-based floor layout generation in accordance with an example of the present disclosure;

FIG. 10 illustrates a flowchart of an example method for digital twin-based floor layout generation in accordance with an example of the present disclosure; and

FIG. 11 illustrates a further example block diagram for digital twin-based floor layout generation in accordance with another example of the present disclosure.

### DETAILED DESCRIPTION

For simplicity and illustrative purposes, the present disclosure is described by referring mainly to examples. In the following description, numerous specific details are set forth in order to provide a thorough understanding of the present disclosure. It will be readily apparent however, that the present disclosure may be practiced without limitation to these specific details. In other instances, some methods and structures have not been described in detail so as not to unnecessarily obscure the present disclosure.

the present disclosure, the terms “a” and “an” are intended to denote at least one of a particular element. As used herein, the term “includes” means includes but not limited to, the term “including” means including but not limited to. The term “based on” means based at least in part on.

Digital twin-based floor layout generation apparatuses, methods for digital twin-based floor layout generation, and non-transitory computer readable media having stored thereon machine readable instructions to provide digital twin-based floor layout generation are disclosed herein. The apparatuses, methods, and non-transitory computer readable media disclosed herein provide an artificial intelligence (AI) based assistant to interactively generate floor plans. The apparatuses, methods, and non-transitory computer readable media disclosed herein provide for interactive creation of floor plans by users and/or designers. Yet further, the apparatuses, methods, and non-transitory computer readable media disclosed herein may facilitate interactive floor plan design of a residential or non-residential facility.

With respect to the apparatuses, methods, and non-transitory computer readable media disclosed herein, human activities and the associated processes may represent key concerns at a preliminary phase of a design process. In this regard, it is technically challenging to capture and utilize user movement across different rooms in terms of footprints, engagement duration, etc., and to utilize this user movement to optimize floor plan generation.

Yet further, with respect to floor plan design, a floor plan design for a home or a non-residential building may be perpetually customizable in that the future of the home may understand occupants' needs of space, mood, and occasion, and these changes may be perpetual and highly personalized. Further, the floor plan design for a home or a non-residential building may be assistive and protective in that a future home may make necessary accommodations based on specific physical limitations of occupants. The floor plan design for a home or a non-residential building may include a workflow that includes a first step including design ideas where inspiration is obtained from disparate sources, a second step including lifestyle analysis where current home and lifestyle aspects are examined, a third step including sketch design where a rough floor plan is sketched, and a fourth step including computer aided design (CAD) design where CAD tools are used to design the floor plan. Further, with respect to floor plan design, tools, such as CAD tools, may be used to design a floor plan. Depending on the complexity of the floor plan design, various levels of expertise may be required for utilization of such tools. In this regard, it is technically challenging to generate a floor plan without expertise in floor plan design or the use of complex designing tools.

The apparatuses, methods, and non-transitory computer readable media disclosed herein address at least the aforementioned technical challenges by generating vectorized floorplans from a boundary layout and a digital twin (e.g., human activity data). In this regard, a human activity map may be utilized to guide floorplan generation. The human activity map may describe human spatial behavior in an interior space, reflecting both the spatial configuration and human-environment interaction of floor layouts. Based on qualitative and quantitative analysis of such metrics, floor plans generated by the apparatuses, methods, and non-transitory computer readable media disclosed herein may provide greater realism and improved quality compared to known techniques.

In one example, the architecture of the digital twin-based floor layout generation apparatus may include a convolutional message passing network (Conv-MPN) analyzer, an image synthesizer (e.g., generator), and a discriminator. The convolutional message passing network analyzer may process input graphs (e.g., an activity map) and generate embedding vectors for each room type. The image synthesizer may synthesize a space layout to generate a floor plan using an input boundary feature map. Further, the discriminator may classify the generated floor plan as real or not-real (e.g., fake).

The apparatuses, methods, and non-transitory computer readable media disclosed herein may provide an end-to-end trainable network to generate floor plans along with doors and windows from a given human activity map. The generated two-dimensional (2D) floor plan may be converted to 2.5D to 3D floor plans. The aforementioned floor plan generation process may also be used to generate floor plans for a single unit or multiple units. The generated floor plan may be utilized to automatically (e.g., without human intervention) control (e.g., by a controller) one or more tools and/or machines related to construction of a structure specified by the floor plan. For example, the tools and/or machines may be automatically guided by the dimensional layout of the floor plan to coordinate and/or verify dimensions and/or configurations of structural features (e.g., walls, doors, windows, etc.) specified by the floor plan. In one example, the generated floor plan may be used to automatically generate 2.5 dimensional (2.5D) or 3D models.

The apparatuses, methods, and non-transitory computer readable media disclosed herein may further provide for the generation of high quality floor plan layouts without any post-processing. For example, compared to known techniques of floor plan generation, the apparatuses, methods, and non-transitory computer readable media disclosed herein may provide a floor plan that is more efficient and easier to build due to the higher quality of the floor plan. In this regard, the apparatuses, methods, and non-transitory computer readable media disclosed herein may provide an end-to-end trainable network to generate floor plans along with doors and windows from a given human activity map. In some examples, user inputs (or requirements) in the form of a graph such as a number of rooms, type, size and the input boundary may be analyzed to generate a floor plan based on the user inputs.

For the apparatuses, methods, and non-transitory computer readable media disclosed herein, the elements of the apparatuses, methods, and non-transitory computer readable media disclosed herein may be any combination of hardware and programming to implement the functionalities of the respective elements. In some examples described herein, the combinations of hardware and programming may be implemented in a number of different ways. For example, the programming for the elements may be processor executable instructions stored on a non-transitory machine-readable storage medium and the hardware for the elements may include a processing resource to execute those instructions. In these examples, a computing device implementing such elements may include the machine-readable storage medium storing the instructions and the processing resource to execute the instructions, or the machine-readable storage medium may be separately stored and accessible by the computing device and the processing resource. In some examples, some elements may be implemented in circuitry.

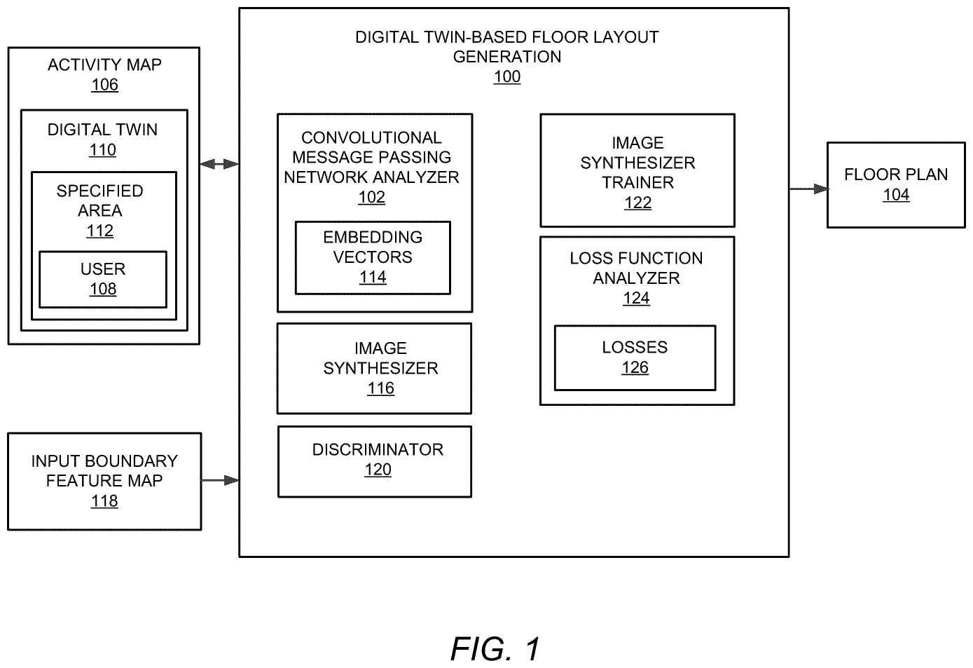

FIG. 1 illustrates a layout of an example digital twin-based floor layout generation apparatus (hereinafter also referred to as “apparatus 100”).

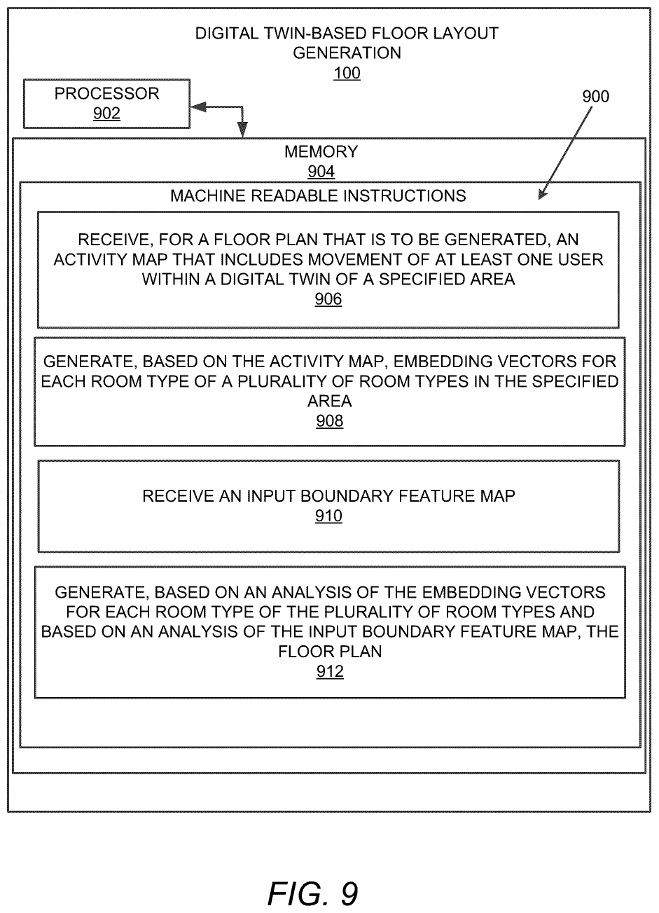

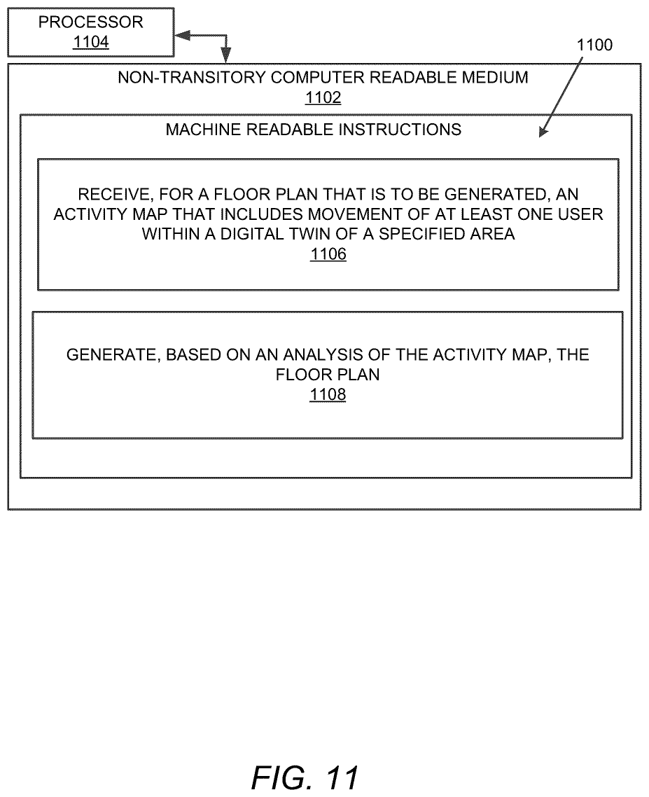

Referring to FIG. 1, the apparatus 100 may include a convolutional message passing network analyzer 102 that is executed by at least one hardware processor (e.g., the hardware processor 902 of FIG. 9, and/or the hardware processor 1104 of FIG. 11) to receive, for a floor plan 104 that is to be generated, an activity map 106 that includes movement of at least one user 108 within a digital twin 110 of a specified area 112. The convolutional message passing network analyzer 102 may generate, based on the activity map 106, embedding vectors 114 for each room type of a plurality of room types in the specified area 112.

An image synthesizer 116 that is executed by at least one hardware processor (e.g., the hardware processor 902 of FIG. 9, and/or the hardware processor 1104 of FIG. 11) may receive an input boundary feature map 118. The image synthesizer 116 may generate, based on an analysis of the embedding vectors 114 for each room type of the plurality of room types and based on an analysis of the input boundary feature map 118, the floor plan 104.

According to examples disclosed herein, the specified area 112 may include a residence or a factory. Alternatively, the specified area 112 may include any type of area or structure for which a floor plan may be generated.

According to examples disclosed herein, the convolutional message passing network analyzer 102 may generate, based on the activity map 106, the embedding vectors 114 for each room type of the plurality of room types in the specified area 112 by passing the activity map 106 through a series of graph convolution layers.

According to examples disclosed herein, the convolutional message passing network analyzer 102 may generate, based on the activity map 106, the embedding vectors 114 for each room type of the plurality of room types in the specified area 112 by utilizing embedding layers to embed the activity map 106 to generate the embedding vectors 114 of a specified dimension.

A discriminator 120 that is executed by at least one hardware processor (e.g., the hardware processor 902 of FIG. 9, and/or the hardware processor 1104 of FIG. 11) may classify the generated floor plan 104 as real or not-real.

An image synthesizer trainer 122 that is executed by at least one hardware processor (e.g., the hardware processor 902 of FIG. 9, and/or the hardware processor 1104 of FIG. 11) may train an image generation network of the image synthesizer 116 adversarially against a discriminator network of the discriminator 120.

According to examples disclosed herein, the image synthesizer trainer 122 may train the image generation network of the image synthesizer 116 adversarially against the discriminator network of the discriminator 120 by minimizing, by the image synthesizer 116, an objective, and maximizing, by the discriminator 120, the objective.

A loss function analyzer 124 that is executed by at least one hardware processor (e.g., the hardware processor 902 of FIG. 9, and/or the hardware processor 1104 of FIG. 11) minimize, for the floor plan that is to be generated, a weighted sum of losses 126.

According to examples disclosed herein, the loss function analyzer 124 may minimize, for the floor plan 104 that is to be generated, the weighted sum of losses 126 that include a referential loss and/or a cost factors loss.

According to examples disclosed herein, the loss function analyzer 124 may minimize, for the floor plan 104 that is to be generated, the weighted sum of losses 126 that include a referential loss that is based on a pixel loss determined as a difference between ground-truth and generated images.

According to examples disclosed herein, the loss function analyzer 124 may minimize, for the floor plan 104 that is to be generated, the weighted sum of losses 126 that include a cost factors loss that is based on an activity loss determined as a specified distance between predicted rooms from the floor plan 104 that is to be generated to minimize movement cost.

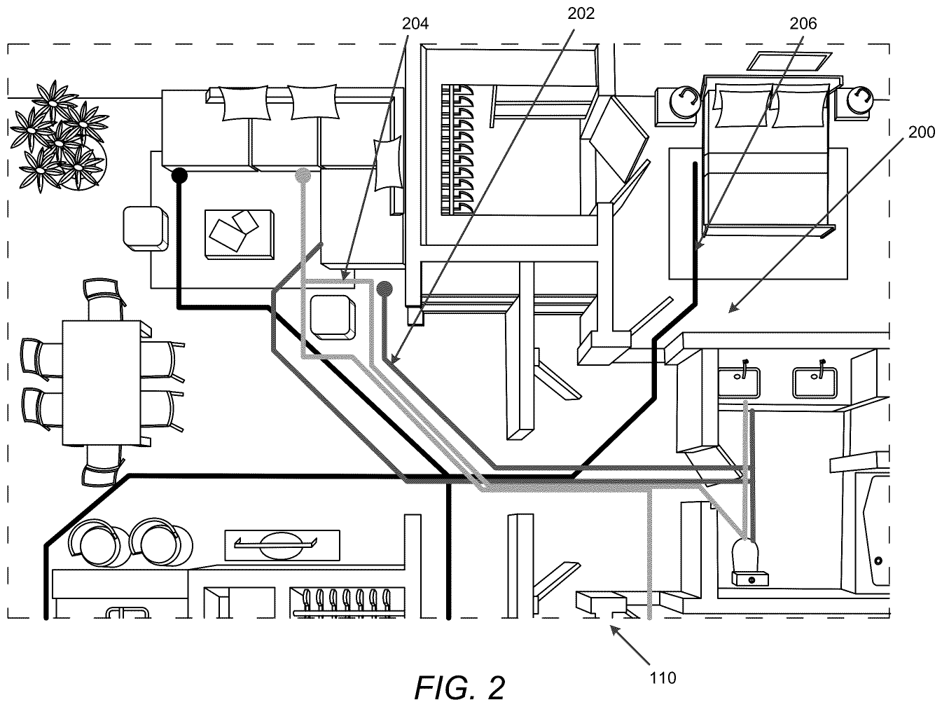

FIG. 2 illustrates a layout of a digital twin of a home to illustrate operation of the apparatus 100, in accordance with an example of the present disclosure.

Referring to FIGS. 1 and 2, as disclosed herein, the convolutional message passing network analyzer 102 may receive, for the floor plan 104 that is to be generated, the activity map 106 that includes movement of at least one user 108 within the digital twin 110 of the specified area 112. The digital twin 110 may include user movement that is captured across different rooms in terms of footprints, engagement duration, etc. For example, as shown at 200, the user movement is shown at 204, 206, and 208 across various rooms of the home.

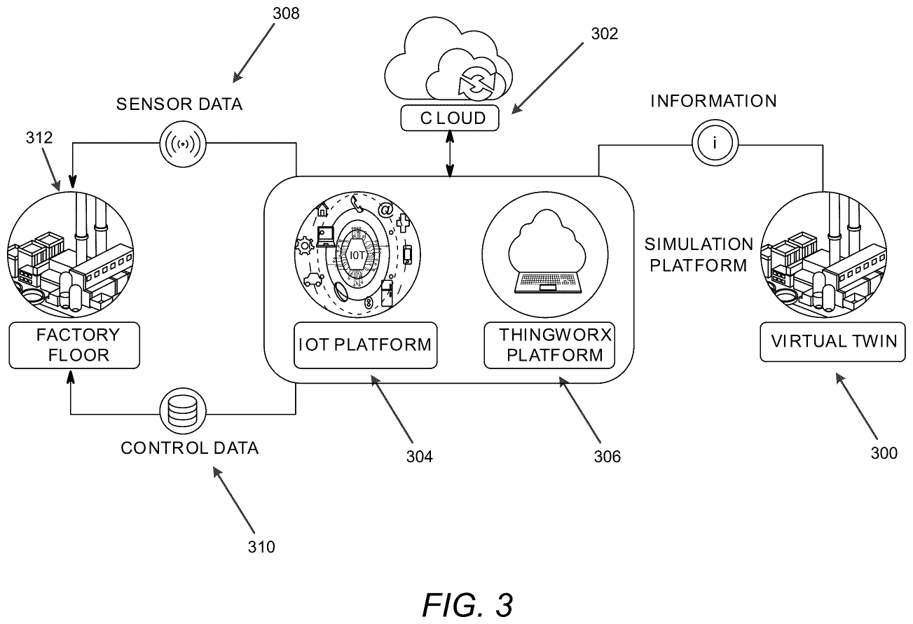

FIG. 3 illustrates a layout of a digital twin of a factory to illustrate operation of the apparatus 100, in accordance with an example of the present disclosure.

Referring to FIG. 3, the digital twin 110 of the factory may be similar to the digital twin 110 of a home as shown in FIG. 2. In this regard, the digital twin 110 of the factory may include information from a simulation platform associated with the factory at 300, as information from cloud data at 302, Internet of Things (IOT) and THINGWORX platforms at 304 and 306, sensor data at 308, and control data at 310. A layout of the factory may be specified at 312.

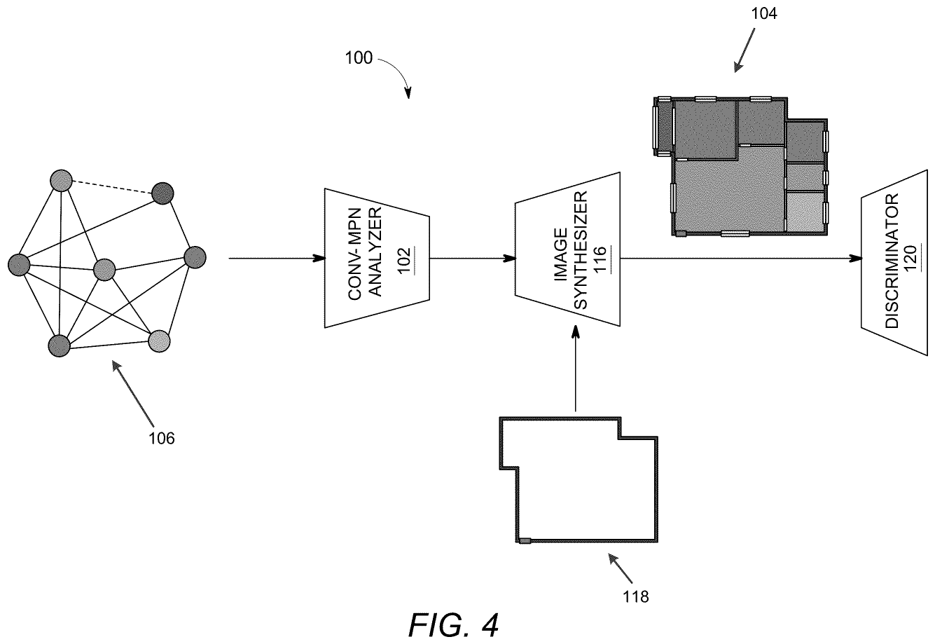

FIG. 4 illustrates an architecture of the apparatus 100, in accordance with an example of the present disclosure.

Referring to FIGS. 1 and 4, the convolutional message passing network analyzer 102 may receive, for the floor plan 104 that is to be generated, the activity map 106 that includes movement of at least one user 108 within the digital twin 110 of the specified area 112. The convolutional message passing network analyzer 102 may generate, based on the activity map 106, embedding vectors 114 for each room type of a plurality of room types in the specified area 112.

The convolutional message passing network analyzer 102 may process input graphs (e.g., the activity map 106) and generate embedding vectors 114 for each room type. The activity map 106 may be passed through a series of graph convolution layers (message passing network) of the convolutional message passing network analyzer 102 that generates the embedding vectors 114.

The embedding layers of the convolutional message passing network analyzer 102 may be used to embed the activity map 106 to produce vectors of dimension Dᵢₙ=256. Given an activity map 106 with vectors of dimension Dᵢₙ at each node and edge, the convolutional message passing network analyzer 102 may determine new vectors of dimension Dₒᵤₜ for each node and edge. Output vectors may be a function of a neighborhood of their corresponding inputs, so that each convolution layer propagates information along edges of the activity map 106. Nodes may denote the units (e.g., rooms or factory units) and edges may denote the connection (with respect to activity, whether movement of a user, or material movement).

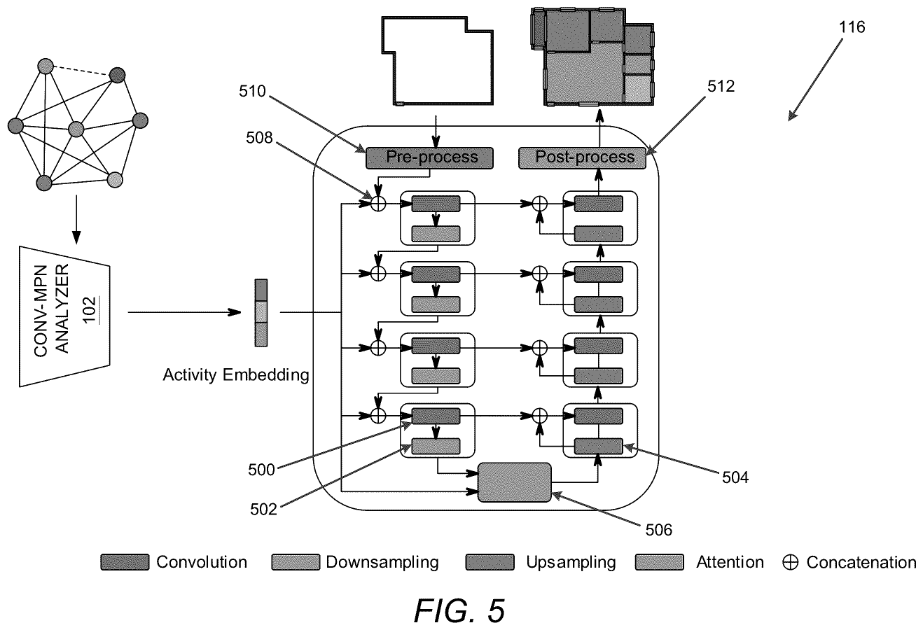

FIG. 5 illustrates an architecture of the image synthesizer 116 of the apparatus 100, in accordance with an example of the present disclosure.

Referring to FIGS. 1, 4, and 5, the image synthesizer 116 may receive the input boundary feature map 118. The image synthesizer 116 may generate, based on an analysis of the embedding vectors 114 for each room type of the plurality of room types and based on an analysis of the input boundary feature map 118, the floor plan 104.

image synthesizer 116 may synthesize a space layout to generate the floor plan 104 using the input boundary feature map 118. In this regard, the image synthesizer 116 may transform the input boundary feature map 118 to the floor plan 104 conditioned on the activity map 106. The image synthesizer 116 may be trained to produce outputs that cannot be distinguished from “real” floor plans by the adversarially trained discriminator 120 (e.g., denoted “D”).

$${ℒ}_{cGAN} ( G , D ) = {𝔼}_{x , y} [ log D ( x , y ) ] + {𝔼}_{x , z} [ log ( 1 - D ( x , G ( x , z ) ) ] \qquad Equation ( 1 )$$

For Equation (1), the image synthesizer 116 (e.g., G) may try to minimize an objective against an adversarial D that tries to maximize the objective. With respect to Equation (1), the image synthesizer 116 may attempt to minimize this function while the discriminator 120 may attempt to maximize it. For Equation (1), D (x) may represent the estimate from the discriminator 120 for the probability that real data instance x is real, Ex may represent the expected value over all real data instances, G (z) may represent the output of the image synthesizer 116 when given noise z, D (G (z)) may represent the estimate of the discriminator 120 for the probability that a fake instance is real, and Ez may represent the expected value over all random inputs to the image synthesizer 116. The encoding path may extract features at every convolutional block by reducing spatial dimensions and enriching the feature dimension, and then passing these features to the decoding path. In turn, the decoding path may convert features to images.

At every basic block in the encoding path, the width and height dimensions may be halved, and the feature dimension may be doubled (except for the first one). The decoding path may process the output from attention through a sequence of up-sampling (e.g., blocks 504 of FIG. 5) and convolution layers (e.g., blocks 500 of FIG. 5). Each basic block may double the width and height, and halve the feature dimension. The pre-process layer 510 may include a convolution and leaky ReLU (rectified linear unit), whereas the post-process layer 512 may include a 1×1-convolution and sigmoid. Attention bridges may be included at the end of the encoding path and start of the decoding path. The attention layer may learn the weights for each embedding based on the activity map 106.

As shown in FIG. 5, with respect to the image synthesizer 116, the architecture of the image synthesizer 116 may further include convolution blocks 500, downsampling blocks 502, upsampling blocks 504, attention block 506, and concatenation operations at 508.

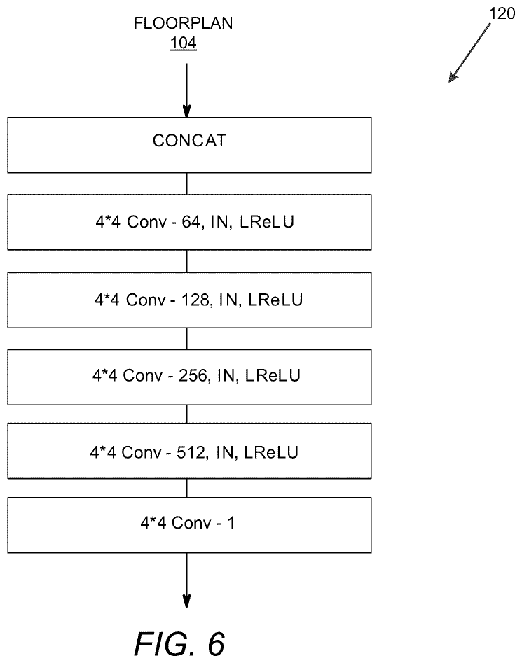

FIG. 6 illustrates an architecture of the discriminator 120 of apparatus 100, in accordance with an example of the present disclosure.

Referring to FIGS. 1, 4, and 6, the discriminator 120 may classify the generated floor plan 104 as real or not-real (e.g., fake). The discriminator 120 may receive the image from the image synthesizer 116 as input, and aim to classify the image as real or not-real (e.g., fake). In this regard, the image synthesizer 116 may generate realistic output images by training the image generation network f (e.g., the image synthesizer 116) adversarially against the discriminator network D (e.g., the discriminator 120). The discriminator 120 may attempt to classify the generated floor plan 104 as real or not-real (e.g., fake) by maximizing the objective as follows:

$${ℒ}_{GAN} = {𝔼}_{x ∼ {p}_{real}} log D ( x ) + {𝔼}_{x ∼ {p}_{fake}} log ( 1 - D ( x ) ) \qquad Equation ( 2 )$$

With respect to the loss functions, the loss function analyzer 124 may minimize a weighted sum of losses as follows. For example, the loss function analyzer 124 may account for referential loss, cost factors loss, and other types of losses as follows.

With respect to referential loss, the loss function analyzer 124 may analyze pixel loss (Lₚ) by determining the L1 difference between ground-truth and generated images. The loss function analyzer 124 may analyze overlap loss (Lₒ) by determining the overlap between predicted room bounding boxes for the generated floor plan 104. The overlap between room bounding boxes may ideally be as small as possible.

With respect to cost factors loss, the loss function analyzer 124 may analyze activity loss (Lₐ) by determining the “Manhattan” distance between predicted rooms of the generated floor plan 104 to minimize movement cost.

With respect to other types of losses, the loss function analyzer 124 may specify an objective to minimize the total cost which may include piping cost, material flow cost, pumping cost, process flow cost, etc., as follows:

$$Total Cost = {\sum }_{i = 1}^{n} {\sum }_{j = 1}^{n} {PC}_{ij} * ( {LD}_{ij} ) + {\sum }_{i = 1}^{n} {\sum }_{j = 1}^{n} {MFC}_{ij} * ( {LD}_{ij} ) + {\sum }_{i = 1}^{n} {\sum }_{j = 1}^{n} {PM}_{ij} * ( {LD}_{ij} ) \qquad Equation ( 3 )$$

For Equation (3), LDᵢⱼ may represent the distance between layouts i and j, measured in terms of the “Manhattan” distance between the layouts. MFCᵢⱼ may represent the material flow cost between layouts i and j. PCᵢⱼ may represent the piping cost between layouts i and j. Lastly, PMᵢⱼ may represent the pumping cost between layouts i and j.

With respect to minimum spacing constraints (e.g., to avoid overlapping) for the generated floor plan 104, the image synthesizer 116 may generate the floor plan 104 to include a layout placement that may satisfy the minimum spacing between the equipment as follows:

$${LD}_{ij} \geq {SP}_{ij} \qquad Equation ( 4 )$$

The minimum spacing constraints may be implemented to ensure the safety of equipment. For Equation (4), SPᵢⱼ may represent the minimum spacing distance between layouts i and j.

With respect to maintenance constraints for the generated floor plan 104, the image synthesizer 116 may generate the floor plan 104 to include, based on maintenance area that is provided along each facility, a maintenance space along each dimensions of a facility.

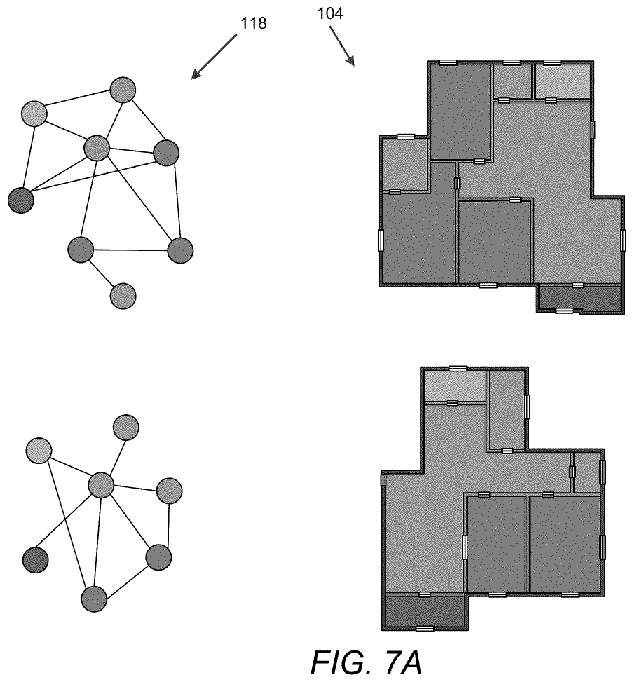

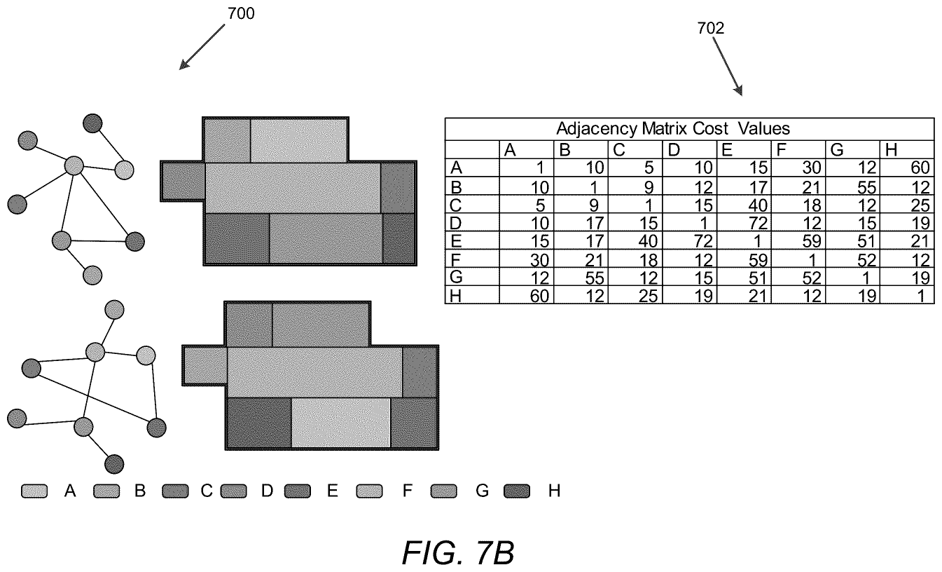

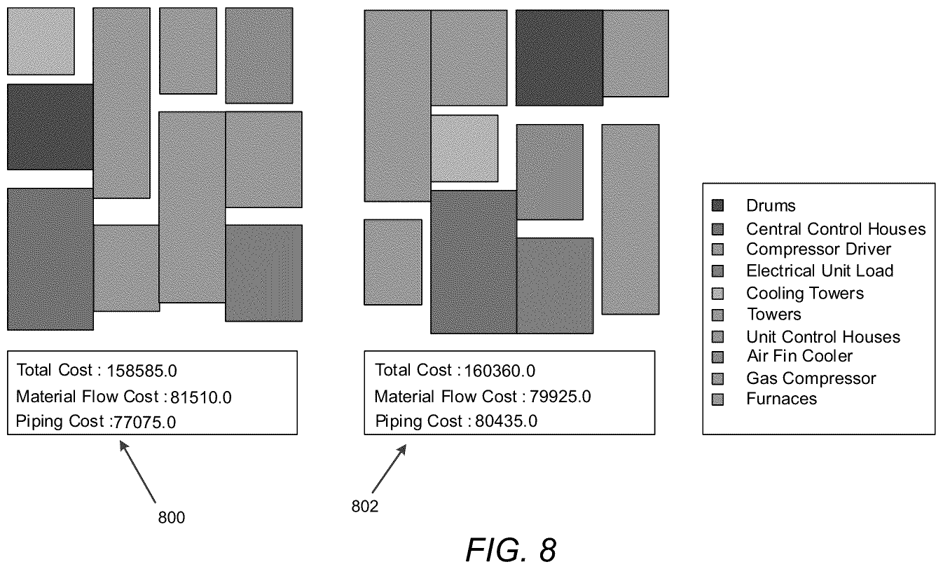

FIGS. 7A and 7B illustrate results to illustrate operation of the apparatus 100, in accordance with an example of the present disclosure. Further, FIG. 8 illustrates results to illustrate operation of the apparatus 100, in accordance with an example of the present disclosure.

Referring to FIGS. 7A, 7B, and 8, as shown, the floor plans generated by the apparatus 100 may utilize the activity map 106 to thus include greater realism and improved quality. Referring to FIG. 7B, nodes may represent the entity or zones, edges may represent the multi-parameter cost values such as man/material movement cost, piping cost, etc. The graph (fully-connected graph) may be represented in the form of an adjacency matrix. The matrix may represent the connection between two zones (e.g., whether two nodes are adjacent or not) or other cost values such as movement cost, piping cost, etc. Between each pair of nodes, there will be some cost value. In graph 700, some edges are omitted, representing low-cost value. The adjacency matrix 702 may represent the cost values between every pair of nodes. Further, the floor plans generated by the apparatus 100 may include minimal costs as shown in FIG. 8 at 800 versus 802. For the example of FIG. 8, the different types of costs may be used to select one of the floor plans, and/or to address a specific cost.

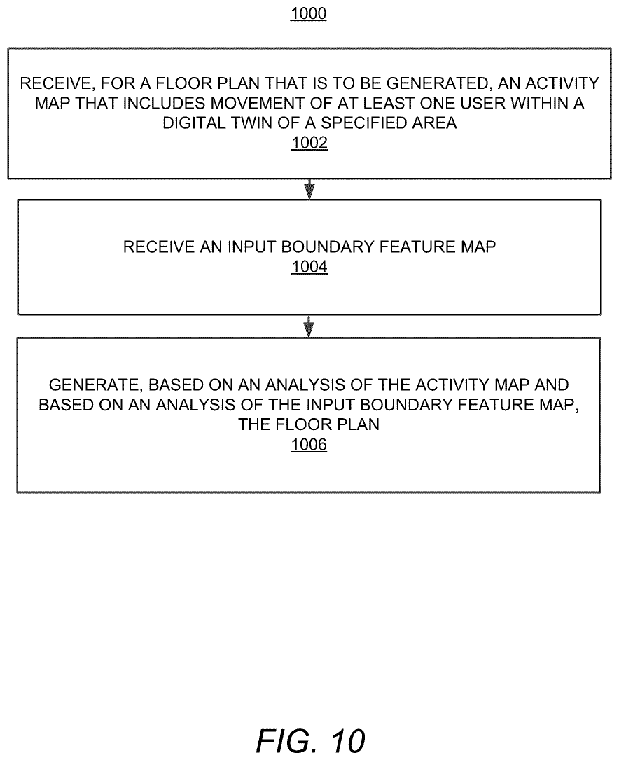

FIGS. 9-11 respectively illustrate an example block diagram 900, a flowchart of an example method 1000, and a further example block diagram 1100 for digital twin-based floor layout generation, according to examples. The block diagram 900, the method 1000, and the block diagram 1100 may be implemented on the apparatus 100 described above with reference to FIG. 1 by way of example and not of limitation. The block diagram 900, the method 1000, and the block diagram 1100 may be practiced in other apparatus. In addition to showing the block diagram 900, FIG. 9 shows hardware of the apparatus 100 that may execute the instructions of the block diagram 900. The hardware may include a processor 902, and a memory 904 storing machine readable instructions that when executed by the processor cause the processor to perform the instructions of the block diagram 900. The memory 904 may represent a non-transitory computer readable medium. FIG. 10 may represent an example method for digital twin-based floor layout generation, and the steps of the method. FIG. 11 may represent a non-transitory computer readable medium 1102 having stored thereon machine readable instructions to provide digital twin-based floor layout generation according to an example. The machine readable instructions, when executed, cause a processor 1104 to perform the instructions of the block diagram 1100 also shown in FIG. 11.

The processor 902 of FIG. 9 and/or the processor 1104 of FIG. 11 may include a single or multiple processors or other hardware processing circuit, to execute the methods, functions and other processes described herein. These methods, functions and other processes may be embodied as machine readable instructions stored on a computer readable medium, which may be non-transitory (e.g., the non-transitory computer readable medium 1102 of FIG. 11), such as hardware storage devices (e.g., RAM (random access memory), ROM (read only memory), EPROM (erasable, programmable ROM), EEPROM (electrically erasable, programmable ROM), hard drives, and flash memory). The memory 904 may include a RAM, where the machine readable instructions and data for a processor may reside during runtime.

Referring to FIGS. 1-9, and particularly to the block diagram 900 shown in FIG. 9, the memory 904 may include instructions 906 to receive, for a floor plan 104 that is to be generated, an activity map 106 that includes movement of at least one user 108 within a digital twin 110 of a specified area 112.

The processor 902 may fetch, decode, and execute the instructions 908 to generate, based on the activity map 106, embedding vectors 114 for each room type of a plurality of room types in the specified area 112.

The processor 902 may fetch, decode, and execute the instructions 910 to receive an input boundary feature map 118.

The processor 902 may fetch, decode, and execute the instructions 912 to generate, based on an analysis of the embedding vectors 114 for each room type of the plurality of room types and based on an analysis of the input boundary feature map 118, the floor plan 104.

Referring to FIGS. 1-8 and 10, and particularly FIG. 10, for the method 1000, at block 1002, the method may include receiving, for a floor plan 104 that is to be generated, an activity map 106 that includes movement of at least one user 108 within a digital twin 110 of a specified area 112.

At block 1004, the method may include receiving an input boundary feature map 118.

At block 1006, the method may include generating, based on an analysis of the activity map 106 and based on an analysis of the input boundary feature map 118, the floor plan 104.

Referring to FIGS. 1-8 and 11, and particularly FIG. 11, for the block diagram 1100, the non-transitory computer readable medium 1102 may include instructions 1106 to receive, for a floor plan 104 that is to be generated, an activity map 106 that includes movement of at least one user 108 within a digital twin 110 of a specified area 112.

processor 1104 may fetch, decode, and execute the instructions 1108 to generate, based on an analysis of the activity map 106, the floor plan 104.

What has been described and illustrated herein is an example along with some of its variations. The terms, descriptions and figures used herein are set forth by way of illustration only and are not meant as limitations. Many variations are possible within the spirit and scope of the subject matter, which is intended to be defined by the following claims—and their equivalents—in which all terms are meant in their broadest reasonable sense unless otherwise indicated.

What is claimed is:

1. A digital twin-based floor layout generation apparatus comprising:
at least one hardware processor;
a convolutional message passing network analyzer, executed by the at least one hardware processor, to:
receive, for a floor plan that is to be generated, an activity map that includes movement of at least one user within a digital twin of a specified area; and
generate, based on the activity map, embedding vectors for each room type of a plurality of room types in the specified area; and
an image synthesizer, executed by the at least one hardware processor, to:
receive an input boundary feature map; and
generate, based on an analysis of the embedding vectors for each room type of the plurality of room types and based on an analysis of the input boundary feature map, the floor plan.

2. The digital twin-based floor layout generation apparatus according to claim 1, wherein the specified area includes a residence or a factory.

3. The digital twin-based floor layout generation apparatus according to claim 1, wherein the convolutional message passing network analyzer is executed by the at least one hardware processor to generate, based on the activity map, the embedding vectors for each room type of the plurality of room types in the specified area by:
passing the activity map through a series of graph convolution layers.

4. The digital twin-based floor layout generation apparatus according to claim 1, wherein the convolutional message passing network analyzer is executed by the at least one hardware processor to generate, based on the activity map, the embedding vectors for each room type of the plurality of room types in the specified area by:
utilizing embedding layers to embed the activity map to generate the embedding vectors of a specified dimension.

5. The digital twin-based floor layout generation apparatus according to claim 1, further comprising:
a discriminator, executed by the at least one hardware processor, to:
classify the generated floor plan as real or not-real.

6. The digital twin-based floor layout generation apparatus according to claim 5, further comprising:
an image synthesizer trainer, executed by the at least one hardware processor, to:
train an image generation network of the image synthesizer adversarially against a discriminator network of the discriminator.

7. The digital twin-based floor layout generation apparatus according to claim 6, wherein the image synthesizer trainer is executed by the at least one hardware processor to train the image generation network of the image synthesizer adversarially against the discriminator network of the discriminator by:
minimizing, by the image synthesizer, an objective.
maximizing, by the discriminator, the objective.

8. The digital twin-based floor layout generation apparatus according to claim 1, further comprising:
a loss function analyzer, executed by the at least one hardware processor, to:
minimize, for the floor plan that is to be generated, a weighted sum of losses.

9. The digital twin-based floor layout generation apparatus according to claim 8, wherein the loss function analyzer is executed by the at least one hardware processor to minimize, for the floor plan that is to be generated, the weighted sum of losses by:
minimizing, for the floor plan that is to be generated, the weighted sum of losses that include at least one of a referential loss or a cost factors loss.

10. The digital twin-based floor layout generation apparatus according to claim 8, wherein the loss function analyzer is executed by the at least one hardware processor to minimize, for the floor plan that is to be generated, the weighted sum of losses by:
minimizing, for the floor plan that is to be generated, the weighted sum of losses that include a referential loss that is based on a pixel loss determined as a difference between ground-truth and generated images.

11. The digital twin-based floor layout generation apparatus according to claim 8, wherein the loss function analyzer is executed by the at least one hardware processor to minimize, for the floor plan that is to be generated, the weighted sum of losses by:
minimizing, for the floor plan that is to be generated, the weighted sum of losses that include a cost factors loss that is based on an activity loss determined as a specified distance between predicted rooms from the floor plan that is to be generated to minimize movement cost.

12. A method for digital twin-based floor layout generation, the method comprising:
receiving, by at least one hardware processor, for a floor plan that is to be generated, an activity map that includes movement of at least one user within a digital twin of a specified area;
receiving, by the at least one hardware processor, an input boundary feature map; and
generating, by the at least one hardware processor, based on an analysis of the activity map and based on an analysis of the input boundary feature map, the floor plan.

13. The method according to claim 12, wherein generating, by the at least one hardware processor, based on the analysis of the activity map and based on the analysis of the input boundary feature map, the floor plan further comprises:
generating, by the at least one hardware processor, based on the activity map, embedding vectors for each room type of a plurality of room types in the specified area; and
generating, by the at least one hardware processor, based on an analysis of the embedding vectors for each room type of the plurality of room types and based on the analysis of the input boundary feature map, the floor plan.

14. The method according to claim 12, further comprising:
classifying, by the at least one hardware processor, the generated floor plan as real or not-real.

15. The method according to claim 14, further comprising:
training, by the at least one hardware processor, an image generation network adversarially against a discriminator network that classifies the generated floor plan as real or not-real.

16. The method according to claim 12, further comprising:
minimizing, by the at least one hardware processor, for the floor plan that is to be generated, a weighted sum of losses.

17. A non-transitory computer readable medium having stored thereon machine readable instructions, the machine readable instructions, when executed by at least one hardware processor, cause the at least one hardware processor to:
receive, for a floor plan that is to be generated, an activity map that includes movement of at least one user within a digital twin of a specified area; and
generate, based on an analysis of the activity map, the floor plan.

18. The non-transitory computer readable medium according to claim 17, wherein the machine readable instructions to generate, based on the analysis of the activity map, the floor plan, when executed by the at least one hardware processor, further cause the at least one hardware processor to:
receive an input boundary feature map; and
generate, based on the analysis of the activity map and based on an analysis of the input boundary feature map, the floor plan.

19. The non-transitory computer readable medium according to claim 18, wherein the machine readable instructions to generate, based on the analysis of the activity map and based on the analysis of the input boundary feature map, the floor plan, when executed by the at least one hardware processor, further cause the at least one hardware processor to:
generate, based on the activity map, embedding vectors for each room type of a plurality of room types in the specified area; and
generate, based on an analysis of the embedding vectors for each room type of the plurality of room types and based on the analysis of the input boundary feature map, the floor plan.

20. The non-transitory computer readable medium according to claim 17, wherein the machine readable instructions, when executed by the at least one hardware processor, further cause the at least one hardware processor to:
minimize, for the floor plan that is to be generated, a weighted sum of losses.
